(19) United States
(12) Patent Application Publication
(10) Pub. No.: US 2026/0196985 A1
(43) Pub. Date: Jul. 9, 2026

(54) RF DIFFERENTIAL CIRCUIT WITH COMMON MODE NOISE REJECTION

(71) Applicant: Taiwan Semiconductor Manufacturing Company, Ltd., Hsinchu (TW)

(72) Inventors: Ho-Ching YEN, Hsinchu (TW); Wei CHANG, Hsinchu (TW); Hsieh-Hung HSIEH, Hsinchu (TW); Tzu-Jin YEH, Hsinchu (TW)

(21) Appl. No.: 19/191,948

(22) Filed: Apr. 28, 2025

Related U.S. Application Data
(60) Provisional application No. 63/742,317, filed on Jan. 6, 2025.

(51) Int. Cl. H03H 11/04

(52) U.S. Cl. CPC H03H 11/0422

(57) ABSTRACT

An RF differential system includes an RF differential circuit and a winding connected to the RF differential circuit. The winding has a center tap. A bias terminal is configured to receive a bias signal. A rejection network is connected between the center tap and the bias terminal.

### CROSS-REFERENCE TO RELATED APPLICATIONS

The present application claims priority from U.S. Provisional Patent Application No. 63/742,317, filed Jan. 6, 2025, the disclosure of which is hereby incorporated by reference in its entirety.

### BACKGROUND

A radio frequency (RF) differential circuit has a pair of signal lines that ideally provide equal and opposite polarity signals, allowing the circuit to effectively eliminate unwanted noise that appears equally on both lines (common-mode noise), while amplifying the intended differential signal between them. The amplification may be achieved, for example, using a differential amplifier circuit. RF differential circuits are used to improve noise reduction, linearity, and stability. For example, an amplifier circuit is often used in RF circuits to amplify weak signals received by the antenna to levels suitable for processing by subsequent circuit stages while adding minimal noise and distortion.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the invention and are not intended to be limiting.

FIG. 1 is a block diagram illustrating aspects of an example RF differential system in accordance with some embodiments.

FIG. 2 is a block diagram illustrating aspects of another example RF differential system in accordance with some embodiments.

FIG. 3 is a circuit diagram illustrating an example amplifier circuit used by the RF differential system of FIG. 1 or 2 in accordance with some embodiments.

FIG. 4 is a circuit diagram illustrating another example amplifier circuit used by the RF differential system of FIG. 1 or 2 in accordance with some embodiments.

FIG. 5 is a block diagram illustrating aspects of a multi-stage RF differential system in accordance with some embodiments.

FIG. 6 is a block diagram illustrating further aspects of a multi-stage RF differential system in accordance with some embodiments.

FIG. 7 is a block diagram illustrating aspects of another example RF differential system in accordance with some embodiments.

FIG. 8 is a circuit diagram illustrating an example rejection network circuit in accordance with some embodiments.

FIG. 9 is a circuit diagram illustrating another example rejection network circuit in accordance with some embodiments.

FIG. 10 is a circuit diagram illustrating a further example rejection network circuit in accordance with some embodiments.

FIG. 11 is a circuit diagram illustrating another example rejection network circuit in accordance with some embodiments.

FIG. 12 is a flow diagram illustrating an example of a method in accordance with disclosed embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An RF differential circuit receives differential input signals that ideally are equal and opposite in polarity, which would allow the circuit to effectively eliminate unwanted noise that appears equally on both lines (common-mode noise) while amplifying the intended differential signal between them. Ideally, the common mode signal in a differential circuit should be zero; i.e., the received differential input signals are equal and opposite in polarity. However, due to mismatches in the circuit in actual implementations, the common mode signal typically cannot be completely canceled. This can result in common mode noise that affects the performance of the RF differential circuit.

In some RF circuit designs, such as RF differential amplifiers, impedance matching circuits are provided between input and output terminals of amplifier stages. Such circuits may include inductors or transformers. For instance, an interstage transformer may be connected between the output terminals of one amplifier stage and the input terminals of the next amplifier stage. This can maintain signal isolation while rejecting common-mode noise between stages. More specifically, the center tap of the transformer or inductor winding is designed to bypass the common mode signal to the VDD and/or AC ground terminal(s) and provide bias to the circuit. However, if common mode noise is injected into the bias network, it can create a feedback loop, and the circuit stability can be compromised by the unwanted common mode noise. This is especially problematic when the circuit operates at high frequencies, which contain significant harmonic effects.

Aspects of the disclosure relate to a common mode rejection network for an RF differential circuit to reduce the common mode noise in the circuit. For instance, some examples add a rejection network between a center tap of a winding element and the bias point to reduce the common-mode noise. The winding element may be winding(s) of a transformer and/or an inductor, for example. The stability, gain, and power efficiency of the RF differential circuit can be improved by the common-mode noise rejection network. This topology can be extended to single or multi-stage amplifiers and LC-VCO circuits with differential structures, for example.

In some disclosed examples, a rejection network is added between the center tap of the winding element and the associated bias point. The rejection network can be constructed by any kind of combination with shunt/series connection. The band pass response (R/L/C value) is designed based on the particular circuit application.

Some examples use passive elements to implement the rejection network for suppressing different types of noises. Different types of filter circuits may be employed, such as various low pass rejection networks for suppressing high-frequency noise and/or a band pass type of rejection network for suppressing low-frequency and high-frequency noise. Further examples use notch type of rejection networks for suppressing noises with the notch frequency.

In other embodiments, the network is implemented with active elements, such as operational amplifiers (Op-Amps), active filters, transistors (BJT, FET, etc.), voltage regulators (linear and switching regulators), active noise-cancelling circuits, phase-locked loops (PLLs), etc.

The rejection network can be added to any kind of RF differential circuit in the RF front-end design, such as in single or multi-stage amplifiers and LC-VCO. The rejection network can be applied to the center tap of a winding element (e.g., transformer or inductor) in any kinds of technologies including CMOS, III-V compound semiconductor, three-dimensional integrated circuit (3DIC), integrated power device (IPD), and the like.

For example, the rejection network may be incorporated into a single-stage RF differential circuit, where the winding element with the center tap is an inductor. The rejection network is added between the center tap of the inductor and the associated bias point.

In other implementations, the rejection networks are incorporated into a multi-stage RF differential circuit, where winding elements with the center tap are the primary winding and/or the secondary winding of a transformer. One rejection network is added between the center tap of the primary winding of the transformer and a first bias point, and another rejection network is added between the center tap of the secondary winding of the transformer and a second bias point. Alternatively, the first bias point may be the VDD connection and the second bias point may be the gate voltage VG2.

The rejection network is incorporated into a LC-VCO RF differential circuit in other examples, where the considered winding element with the center tap is an inductor and the rejection network is added between the center tap of the inductor and the associated bias point.

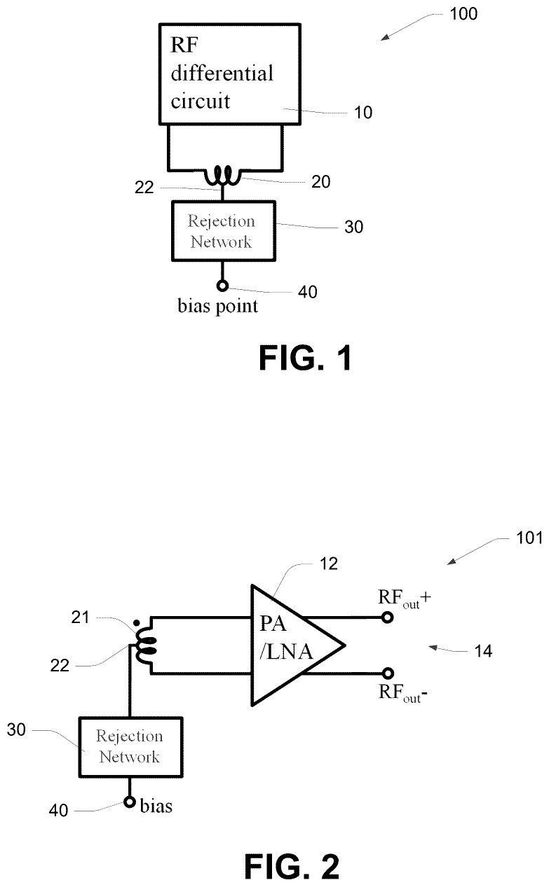

FIG. 1 is a block diagram illustrating aspects of an RF differential system 100, such as an RF amplifier system. The system 100 included an RF differential circuit 10. A winding 20 is connected to the RF differential circuit 10, and the winding 20 has a center tap 22. A rejection network 30 is connected between the center tap 22 and a bias terminal 40, such as a VDD or gate voltage VG terminal. As will be described further below, in some implementations, the winding 20 is an inductor winding or a primary or secondary transformer winding. As will also be discussed below, the RF differential circuit may include any of several types of differential circuits, such as an amplifier circuit, a multi-stage amplifier circuit, a voltage controlled oscillator (VCO) circuit, etc.

FIG. 2 illustrates an example system 101 where the RF differential circuit is a differential amplifier 12, such as a power amplifier or low noise amplifier (LNA). The amplifier 12 is configured to receive and amplify an RF differential input signal, and provide the amplified RF differential signal at differential RF output terminals 14. An inductor 21 provides the winding, which is connected to inputs of the amplifier 12. The inductor 21 includes the center tap 22 and the rejection network 30 is connected between the center tap 22 and the bias terminal 40, such as a VDD or VG terminal. The stability, gain, and power efficiency of the differential amplifier 12 can be improved by the common-mode noise rejection network 30.

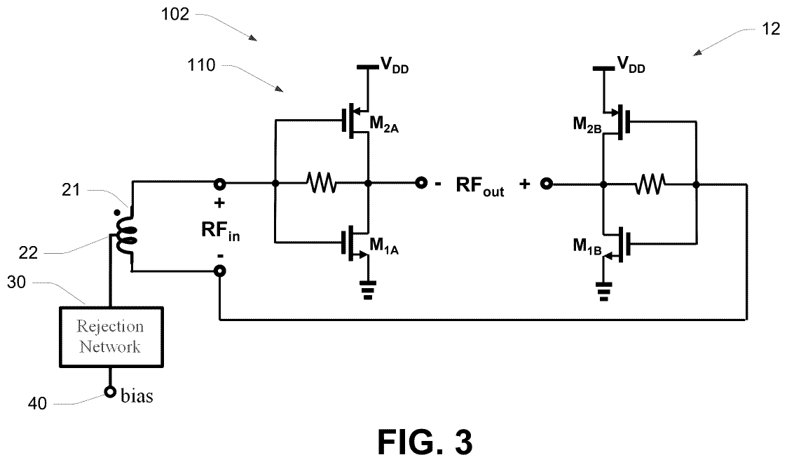

FIG. 3 illustrates an example system 102 in which the amplifier 12 is a differential LNA 110. The LNA circuit 110 is implemented using a complementary, cascoding design in a differential mode. The LNA circuit 110 includes of a pair of NMOS transistors M1A, M1B and a pair of PMOS transistors M2A, M2B arranged in a differential configuration. Positive and negative input terminals receive a differential input signal (RFin) and are respectively connected to gate terminals of the transistors M1A and M2A, and the gate terminals of the transistors M1B and M2B, such that the input signal RFin is received at the gate terminals of the NMOS transistors M1A and M1B and the gate terminals of the PMOS transistors M2A and M2B.

The source terminals of M1A and M1B are connected to a common ground. The drain terminals of M1A and M1B are coupled to the drain terminals of the PMOS transistors M2A, M2B, which serve as active loads. The PMOS transistors' M2A, M2B source terminals are connected to the supply voltage VDD. The drain terminals of the PMOS transistors M2A, M2B and the drain terminals of the NMOS transistors M1A, M1B are coupled to the differential output terminals RFout.

Bias resistors R1, R2 may be connected between the gate terminals and drain terminals of the PMOS transistors M2A, M2B and NMOS transistors M1A, M1B to help set the DC operating point of the PMOS transistors M2A, M2B and to ensure that the gate voltage self-biases to the correct level by creating a feedback path that stabilizes the PMOS transistors M2A, M2B. The inductor 21 is connected across the positive and negative input terminals RFin+/−, and the rejection network 30 is connected between the center tap 22 of the inductor 21 and the bias terminal 40.

The operation of the LNA is based on the transconductance (gm) of the NMOS transistors M1A, M1B and the output resistance (rout) of the PMOS transistors M2A, M2B. When an input signal is applied at RFin, the NMOS transistors amplify the signal, with their gate-source voltage controlling the current flow. The PMOS transistors act as load devices, converting the amplified signal into an output voltage at RFout.

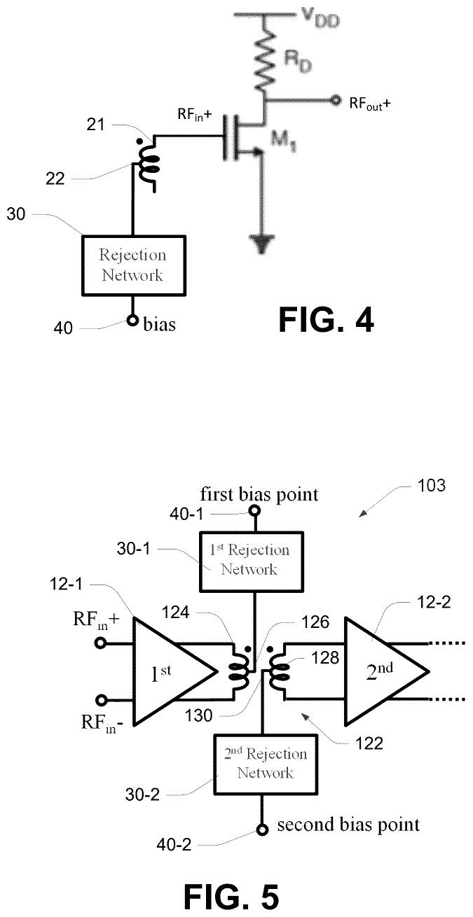

FIG. 4 illustrates a further example where the amplifier 12 includes a differential common source circuit. For simplicity, only one side of the differential amplifier circuit is shown, with the one of the RF signal inputs RFin+ shown connected to the inductor 22 and amplifier circuit 112. The common source amplifier circuit 112 includes a CMOS transistor M1 receiving an input signal RFin+ at its gate terminal and an output node RFout+ at its drain terminal. A mirror image of the circuit 112 would receive the differential input signal RFin− output an amplified RFout− signal. A load resistor RD is connected between the drain terminal of the transistor M1 and a VDD terminal. The transistor M1 converts variations in the gate-source voltage into a small signal drain current which passes through the resistive load RD and generates the amplified voltage across the load resistor RD. The inductor 21 is connected to the positive input terminal RFin+ (and the negative input terminal RFin− though not shown in FIG. 4 as noted above). The rejection network 30 is connected between the center tap 22 of the inductor 21 and the bias terminal 40.

FIG. 5 illustrates an example where multiple rejection networks are incorporated into a multi-stage RF differential circuit. The windings 20 with the center tap 21 are the primary winding and/or the secondary winding of a transformer 122.

More particularly, the system 103 shown in FIG. 5 includes a differential amplifier circuit including a first amplifier stage 12-1 and a second amplifier stage 13. A transformer 122 is connected between output terminals of the first amplifier stage 12-1 and input terminals of the second amplifier stage 12-2. The transformer 122 has a primary, or first winding 124 with a first center tap 126 and a secondary, or second winding 128 having a second center tap 130. A first rejection network 30-1 is connected between the first center tap 126 and a first bias terminal 40-1, and a second rejection network 30-2 is connected between the second center tap 130 and a second bias terminal 40-2. As noted above, the first and second amplifier circuits 12-1, 12-2 may be power amplifier or LNA circuits, such as the examples shown in FIG. 3 and FIG. 4.

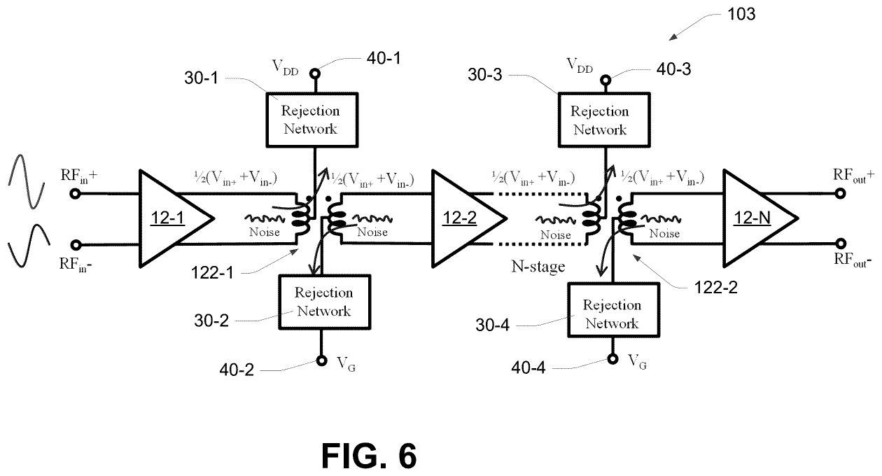

FIG. 6 illustrates further aspects of the multi-stage RF differential circuit 103 shown in FIG. 5. The multi-stage RF differential circuit 103 includes the first amplifier stage 12-1, the second amplifier stage 12-2 and any number N of additional amplifier stages up to amplifier stage 12-N. A transformer 122 is connected between the output terminals of one amplifier stage and input terminals of the subsequent amplifier stage. Thus, in the example of FIG. 6, a first transformer 122-1 is connected between the output terminals of the first amplifier stage 12-1 and input terminals of the second amplifier stage 12-2, and a second transformer 122-2 is connected between the output terminals of the second amplifier stage 12-2 and input terminals of the next (i.e. final) amplifier stage 12-N. Each of the transformers shown in FIG. 6 are configured similarly to the transformer 122 shown in FIG. 5. As such, the first transformer 122-1 has its first center tap 126 connected to the first rejection network 30-1, which is also connected to the first bias terminal 40-1. The second center tap 130 of the first transformer 122-1 is connected to the second rejection network 30-1, which is connected to the second bias terminal 40-1.

Similarly, the second transformer 122-2 has its first center tap 126 connected to a third rejection network 30-3, which is connected to a third bias terminal 40-3. The second center tap 130 of the second transformer 122-2 is connected to a fourth rejection network 30-4, which is connected to a fourth bias terminal 40-4. The first and third bias terminals 40-1 and 40-3 are VDD terminals in FIG. 6, while the second and fourth bias terminals 40-2 and 40-4 are VG terminals.

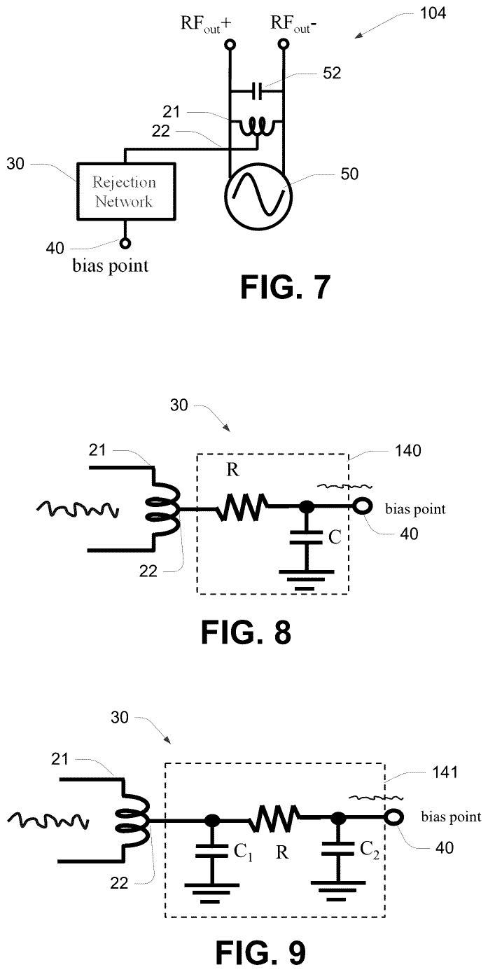

FIG. 7 illustrates a further example 104 in which the differential circuit includes an inductor-capacitor (LC) voltage controlled oscillator (VCO) circuit. The system 104 includes an inductor 21 connected in parallel with a capacitor 52. The parallel-connected inductor 21 and capacitor 52 determine a frequency of oscillation, which can be varied by an applied control voltage 50. The rejection network 30 is connected between the center tap 22 of the inductor 21 and the bias terminal 40, which could be VDD terminal or VG terminal.

Referring back to FIG. 6, the common-mode signals are represented by ½(Vᵢₙ₊+Vᵢₙ₋). Ideally, the common-mode signals would be equal and thus cancelled at the transformer center taps. However, since the common-mode signals typically are mismatched, noise signals can be generated and passed as noise to the bias network acting as a feedback loop. This can impact and degrade the circuit performance.

The rejection networks 30 are configured to reduce such common-mode noise. The rejection networks 30 may be implemented with various circuit topologies, including passive and/or active elements. FIGS. 8-11 illustrate various examples of circuits employing passive elements implementing embodiments of the rejection networks 30. FIG. 8 illustrates an example rejection network 30 that includes a low pass filter circuit 140. The RC low pass filter circuit 140 is configured for suppressing high-frequency noise, and includes a resistor R connected to the center tap 22 of the conductor 21. A capacitor C is connected between the bias terminal 40 and ground, and the output is taken across the capacitor C. At low frequencies the capacitor C has a high reactance and thus operates like an open circuit. Most of the input voltage appears across the capacitor, so the output voltage remains high. At high frequencies the capacitor C reactance decreases and thus starts functioning like a short circuit, shunting high-frequency signals to ground. This results in a lower output voltage.

FIG. 9 illustrates another example of the rejection network 30 that includes a band pass filter circuit 141. The band pass filter circuit 141 is configured to suppress low-frequency and high-frequency noise while allowing a desired frequency signal to pass. Two capacitors C1 and C2 are connected in the band pass configuration with a resistor R. More specifically, the first capacitor C1 connected between the center tap 22 and ground, and the second capacitor C2 is connected between the bias terminal 40 and ground. The resistor R is connected between the center tap 22 and the bias point 40. The band pass circuit 141 of FIG. 9 combines low pass and high pass filters to allow a desired middle frequency band to pass. At low frequencies the reactance of the capacitor C is high, so it blocks low-frequency signals. At high frequencies the reactance of the capacitor C is low, so it effectively shorts high-frequency signals to ground. At mid frequencies (i.e. the “passband”) the circuit allows signals to pass with minimal attenuation.

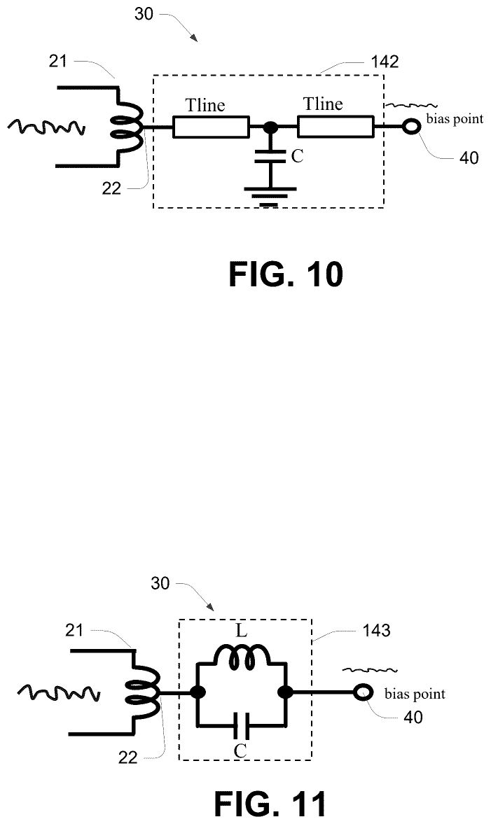

FIG. 10 illustrates another embodiment of the rejection network 30 including a low pass filter circuit 142. The low-pass filter circuit 142 has two transmission lines Tlines connected in series between the center tap 22 and device terminal 40. A capacitor C is connected between the junction of the transmission lines and ground. As with the low pass filter circuit 140 shown in FIG. 8, the low pass filter circuit 142 passes signals with frequencies below a certain cutoff frequency while attenuating signals above that frequency. The transmission lines Tline inherently act as low-pass filters because their impedance changes with frequency, limiting the bandwidth of the signal they can carry. As such, higher frequency signals will be rejected.

FIG. 11 illustrates an example rejection network 30 that employs a notch filter 143. The notch filter 143 includes an LC circuit with an inductor L connected in parallel with a capacitor C between the center tap 22 at the bias terminal 40. An LC notch filter 143 is configured to attenuate a specific frequency while allowing frequencies above and below it to pass with minimal attenuation. The parallel connected inductor L and capacitor C are connected in series with the signal path. At the resonant frequency the LC circuit presents a high impedance, blocking the signal. Other frequencies pass through with little attenuation.

The rejection network 30 could include various combinations of components in shunt/series connection. The band pass response (R/L/C value) may be designed based on the particular circuit application.

In other examples, the rejection network 30 may be formed with active components or circuits, such as operational amplifiers (Op-Amps), active filters, transistors (BJT and FET), voltage regulators (linear and switching regulators), active noise-cancelling circuits, phase-locked loops (PLLs), and the like. Moreover, the rejection networks 30 could be added to other RF differential circuits than shown herein, and is applicable to various technologies including CMOS, III-V compound semiconductors, three-dimensional integrated circuits (3DIC), integrated power devices (IPD), etc.

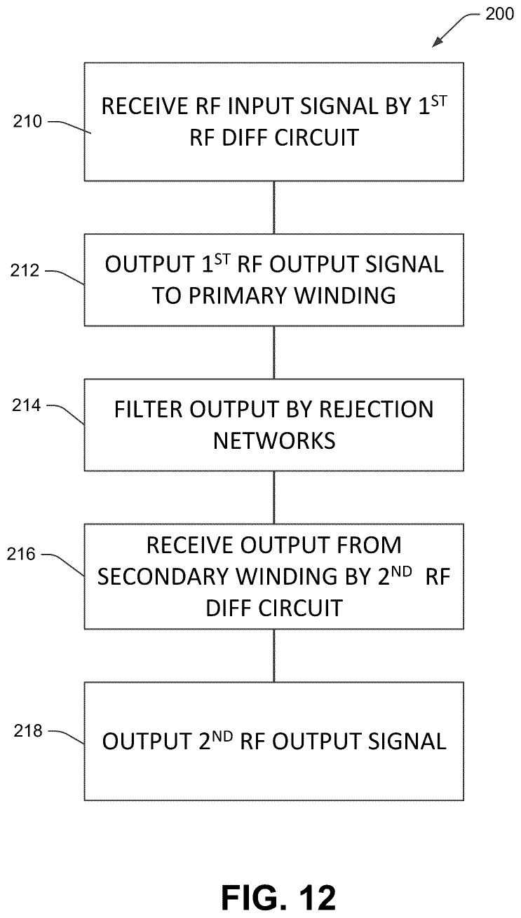

FIG. 12 is a flow diagram illustrating a method 200 for common noise reduction in an RF differential circuit, such as the various RF differential circuits discussed above. Referring to FIG. 12 together with FIG. 5, an RF differential input signal RFin+/RFin− is received by a first RF differential circuit 12-1 at operation 210. At operation 212, a first RF differential output signal is output from the first RF differential circuit 12-1 to a primary winding 124 of a transformer 122. The first RF differential output signal is filtered by a first rejection network 30-1 connected between a first center tap 126 of the primary winding 124 and a first bias signal 40-1 and by a second rejection network 40-2 connected between a second center tap 130 of a secondary winding 128 of the transformer 122 and a second bias signal 40-2 at operation 214. The first RF differential output signal is received from the secondary winding 128 by a second RF differential circuit 12-2 at operation 216. At operation 218, a second RF differential output signal is output from the second RF differential circuit 12-2.

As noted above, in some embodiments the first RF differential circuit 12-1 and the second RF differential circuit 12-2 are amplifier circuits, such as an LNA. As such, the RF differential input signal is amplified to generate the first RF differential output signal, and the first RF differential output signal is amplified by the second RF differential circuit. The first bias signals are a VDD signal and/or a VG signal in some examples.

Thus, various aspects of the disclosure provide a common mode rejection network for an RF differential circuit to reduce common mode noise in the circuit. Several embodiments are disclosed, accommodating a wide variety of circuit topologies for RF differential circuits. The disclosed common mode rejection topologies improve the RF circuit's stability, gain, noise performance, etc.

In accordance with aspects of the disclosure, an RF system includes an RF differential circuit. A winding is connected to the RF differential circuit and includes a center tap. A bias terminal is configured to receive a bias signal, and a rejection network is connected between the center tap and the bias terminal.

In accordance with further aspects, an RF amplifier system includes a differential amplifier circuit having a first amplifier stage and a second amplifier stage. A transformer is connected between output terminals of the first amplifier stage and input terminals of the second amplifier stage. The transformer has a first winding with a first center tap and a second winding having a second center tap. A first bias terminal and a second bias terminal are each configured to receive bias signals. A first rejection network is connected between the first center tap and the first bias terminal, and a second rejection network is connected to between the second center tap and the second bias terminal.

In accordance with additional aspects of the disclosure, a method for addressing common-mode noise in an RF differential circuit includes receiving an RF differential input signal by a first RF differential circuit, and outputting a first RF differential output signal from the first RF differential circuit to a primary winding of a transformer. The first RF differential output signal is filtered by a first rejection network connected between a first center tap of the primary winding and a first bias signal, and by a second rejection network connected between a second center tap of a secondary winding of the transformer and a second bias signal. The first RF differential output signal is received from the secondary winding by a second RF differential circuit. A second RF differential output signal is output from the second RF differential circuit.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system, comprising:
an RF differential circuit;
a winding connected to the RF differential circuit and including a center tap;
a bias terminal; and
a rejection network connected between the center tap and the bias terminal.

2. The system of claim 1, further comprising an inductor, wherein the inductor includes the winding with the center tap.

3. The system of claim 1, wherein the RF differential circuit includes a differential amplifier circuit.

4. The system of claim 3, wherein the differential amplifier circuit is a multi-stage differential amplifier circuit including first and second amplifier stages.

5. The system of claim 1, wherein the RF differential circuit includes a voltage controlled oscillator (VCO) circuit.

6. The system of claim 1, wherein the bias terminal is one of a VDD terminal or a VG terminal.

7. The system of claim 1, wherein the rejection network includes a low pass filter circuit.

8. The system of claim 1, wherein the rejection network includes a band pass filter circuit.

9. The system of claim 1, wherein the rejection network includes a notch filter circuit.

10. A system, comprising:
a differential amplifier circuit including a first amplifier stage and a second amplifier stage;
a transformer connected between output terminals of the first amplifier stage and input terminals of the second amplifier stage, the transformer including a first winding having a first center tap and a second winding having a second center tap;
a first bias terminal;
a second bias terminal;
a first rejection network connected between the first center tap and the first bias terminal; and
a second rejection network connected to between the second center tap and the second bias terminal.

11. The system of claim 10, wherein the first and second amplifier stages each include a common source amplifier circuit.

12. The system of claim 10, wherein the first and second amplifier stages each include a cascode amplifier circuit.

13. The system of claim 10, wherein the first and second rejection networks each include a filter circuit.

14. The system of claim 10, wherein the first and second rejection networks include active elements.

15. The system of claim 10, wherein the first bias point is a VDD terminal, and the second bias point is a VG terminal.

16. The system of claim 10, wherein the differential amplifier circuit includes a third amplifier stage and wherein the transformer is a first transformer, the system further comprising:
a second transformer connected between output terminals of the second amplifier stage and input terminals of the third amplifier stage, the second transformer including a third winding having a third center tap and a fourth winding having a fourth center tap;
a third bias terminal;
a fourth bias terminal;
a third rejection network connected between the third center tap and the third bias terminal; and
a fourth rejection network connected to between the fourth center tap and the fourth bias terminal.

17. A method, comprising:
receiving an RF differential input signal by a first RF differential circuit;
outputting a first RF differential output signal from the first RF differential circuit to a primary winding of a transformer;
filtering the first RF differential output signal by a first rejection network connected between a first center tap of the primary winding and a first bias signal and by a second rejection network connected between a second center tap of a secondary winding of the transformer and a second bias signal;
receiving the first RF differential output signal from the secondary winding by a second RF differential circuit; and
outputting a second RF differential output signal from the second RF differential circuit.

18. The method of claim 17, further comprising:
amplifying the RF differential input signal by the first RF differential circuit; and
amplifying the first RF differential output signal by the second RF differential circuit.

19. The method of claim 17, wherein the first bias signal is a VDD signal.

20. The method of claim 17, wherein the second bias signal is a VG signal.
